(19) United States
(12) Patent Application Publication
(10) Pub. No.: US 2012/0018096 A1
(43) Pub. Date: Jan. 26, 2012

(54) PROCESS CHAMBER HAVING MODULATED PLASMA SUPPLY

(76) Inventor: Roland Gesche, Seligenstadt (DE)

(21) Appl. No.: 13/260,901

(22) PCT Filed: Mar. 31, 2010
(86) PCT No.: PCT/EP10/54340

§ 371 Date: Sep. 28, 2011

(30) Foreign Application Priority Data
Apr. 6, 2009 (DE) 10 2009 016 701.3

(51) Int. Cl. H05H 1/46; C23C 14/34; C23F 1/00; C23C 14/28

(52) U.S. Cl. 156/345.28; 118/50.1; 204/298.08; 204/298.34; 156/345.1; 204/298.03; 204/298.32

(57) ABSTRACT

The invention relates to a plasma chamber (10, 20, 30) having a first receiving device for a substrate (14, 24, 34) fastened to a first side and having a plasma generation unit for generating a plasma in the plasma chamber, wherein the plasma generation unit is connected or can be connected to a high frequency voltage supply (11, 21, 31). The high frequency voltage supply is designed to generate a modulated, high-frequency alternating voltage and to output said voltage to the plasma generation unit. The plasma generation unit is designed to generate the plasma using the modulated, high-frequency alternating voltage.

### BACKGROUND OF THE INVENTION

Plasmaprocesses with high-frequency excitation have a wide variety of applications, particularly in surface technology. These include the coating of surfaces by sputtering or PECVD, etching by means of physical (sputter etching), chemical (plasma etching) or mixed action (reactive ion etching, RIE), as well as the activation, cleaning and modification of surfaces.

Important process parameters in this case are the plasma density and kinetic energy of the particles produced in the plasma, particularly the mean ion velocity.

The plasma density is linked to the power density and creates a measure of overall effectiveness to which the ion current, for example, is connected.

The kinetic energy of the ions (ion energy) is physically connected directly to the mean ion velocity and occurs during high-frequency excitation through the self-bias potential. The self-bias potential acts as the acceleration voltage on the free charge carriers in the plasma and is therefore a significant process parameter, control of which is desirable, in order to create reproducible process conditions. The self-bias potential is a DC voltage and is generated by the rectifying effect of the plasma. This effect occurs in a frequency range from kHz to approx. 100 MHz and originates from the different movability of the ions and free electrons in the plasma. The free electrons possess particularly high mobility due to their low weight and therefore diffuse away from their point of origin (high concentration) more quickly than ions with the opposite electrical charge. Space charge zones, the electrical action of force of which opposes the diffusion of electrons, are formed in this way. The voltage acting between the space charge zones is the aforementioned self-bias potential and represents the effective acceleration voltage for ions during sputtering, sputter-etching and RIE. It is therefore desirable, depending on the procedural application, for the self-bias potential to be capable of being adjusted. There are various known methods of achieving this, however they all have the disadvantage of mutual dependency on the plasma density and kinetic energy of the ions:

### Pressure

The self-bias potential depends, among other things, on the pressure prevailing in the plasma chamber and therefore the plasma density. At higher pressures, the self-bias potential drops due to the increasing plasma density and the decreasing diffusion width resulting from this. However, there is only a limited process window in this case; higher pressures lead to instability and inhomogeneity.

### Magnetic Plasma Confinement

Magnetron cathodes are widely used in sputter-coating processes. Magnetic confinement leads to an increase in plasma density and a reduction in self-bias potential, which results in a higher coating rate. The disadvantage of this is that the target is removed very unevenly and the coating therefore becomes non-homogeneous, which usually has to be balanced out through movement of the substrates being coated. Magnetic plasma confinements have not proved successful in the case of etching and PECVD processes, because the aforementioned lack of homogeneity can only be poorly compensated with the static processes customary here.

### Processes Using Two Electrodes

In different plasma processes, the plasma is generated using a first electrode and extracted using a second electrode located beneath the substrate. The acceleration voltage in this case may be indicated within a certain framework, independently of the plasma generation, via the substrate electrode. The disadvantage of all processes in this category is that two supplies with compensating networks, vacuum tubes and electrodes or antennas are needed, which is expensive and in many cases hard or even impossible to execute (e.g. substrate bias in the case of moved substrates).

A device is therefore needed that permits independent adjustment of the plasma density and ion energy wherever possible. The problem addressed by the invention is therefore one of introducing a plasma chamber that enables the self-bias potential (or the self-bias voltage) to be adjusted and therefore reproducible conditions in the plasma to be created wherever possible.

### SUMMARY OF THE INVENTION

The invention solves the problem by means of a plasma chamber with a first receiving device for a substrate fastened to a first side and with a plasma generation unit for generating plasma in the plasma chamber. The plasma generation unit contains, for example, a sputter target, an electrode or an antenna for generating plasma and is connected or can be connected to a high-frequency voltage supply, which is designed according to the invention to generate a modulated, high-frequency AC voltage and to deliver it to the plasma generation unit. The plasma generation unit is designed to generate the plasma using the modulated, high-frequency AC voltage.

The basic idea behind the invention is to use the non-linearity of the plasma as the electric mixer and thereby make the plasma into an electrical supply component. By supplying the plasma with a modulated signal, mixing products result in the plasma, of which the differential frequencies, in particular, can be advantageously used in the process. In this way, a component of the modulated, high-frequency AC voltage, demodulated in this way in the plasma from the modulated, high-frequency AC voltage, may be advantageously used to adjust the self-bias potential. This adjustment may involve the generation of a self-bias potential by the modulated, high-frequency AC voltage or, however, a suitable change in an existing or self-adjusting self-bias potential to a desired value. Various types of modulation are conceivable in this case, such as, for example, amplitude modulation, phase modulation, frequency modulation or quadrature modulation. Likewise, dual-tone and multi-tone signals may be used.

In the context of the invention, “high-frequency” is understood to mean a frequency that is high enough to act as the carrier frequency for a signal capable of generating the aforementioned self-bias potential. The modulated signal therefore preferably has a frequency in the range of approx. 1 kHz to approx. 100 MHz. The carrier frequency may lie at the upper end of this frequency range or higher, preferably over 70 MHz. It is possible, however, to work with a carrier frequency in the kHz or MHz range and to select a lower frequency as the difference frequency, which, however, should also lie at least within the kHz range.

The plasma chamber may display a user interface for the input of a rated voltage value. In this case, the high-frequency voltage supply is designed to generate the modulated, high-frequency AC voltage at an amplitude indicated by the rated voltage value of a modulated signal.

In this embodiment, the modulated, high-frequency AC voltage generated by the high-frequency power supply and therefore the self-bias potential can be directly influenced by indicating a desired rated voltage value. Of course, other parameters can also be adjusted by the user interface, such as, for example, depending on the type of modulation used, carrier frequency or modulated signal frequencies.

The plasma chamber may have a measuring device, which is designed to determine a self-bias potential of the plasma in the plasma chamber and to deliver it as a measured value. The self-bias potential actually present in the plasma can thereby be determined, so that the parameters for the plasma process can be adjusted where necessary.

The plasma chamber may have a control unit alongside the user interface and the measuring device, which is connected to the user interface, the high-frequency voltage supply and the measuring device and is designed to compare the measured value of the measuring device and the rated voltage value and to regulate the high-frequency voltage supply in accordance with a result of the comparison, if the measured value on the measuring device deviates from the voltage value entered through the user interface. In this way, a control system emerges, which is able to monitor the self-bias potential in a known manner and adjust it to the rated voltage value.

The modulated high-frequency AC voltage may exhibit a mid-band frequency and a bandwidth, in which case the mid-band frequency is preferably between 50 kHz and 10 GHz. The bandwidth is preferably smaller than the mid-band. frequency, particularly preferably smaller than half the mid-band frequency.

In an embodiment of the invention, the modulated, high-frequency AC voltage exhibits at least a first tone of a first frequency and a second tone of a second frequency. The second frequency differs from the first frequency by a difference frequency. In this embodiment, the non-linearity of a gas discharge located in the operation in the plasma chamber produces an AC voltage in the plasma with the frequency of the difference frequency. This AC voltage acts as an acceleration voltage for the ions in the plasma and may be adjusted independently of the plasma generation with regard to amount and frequency. Particularly preferably, the difference frequency is at least 25 kHz and maximum 100 MHz.

The modulated, high-frequency AC voltage may also be a multi-tone signal, in other words, it may have a multiplicity of tones. It is conceivable in this case that the tones will be disposed equidistantly, in order to amplify the AC voltage lying above the plasma, due to the non-linearity of the latter, with the frequency of the difference frequency. It is likewise conceivable that several different difference signals are generated, which can be summarily superimposed on the plasma, e.g. into a desired periodic waveform of the AC voltage.

Alternatively, the modulated, high-frequency AC voltage may be an amplitude-modulated or digital-modulated signal. Also alternatively, the modulated, high-frequency AC voltage may be a phase- or frequency-modulated signal.

All embodiments of the invention may have a second receiving device for a target on a second side.

### BRIEF DESCRIPTION OF THE ILLUSTRATIONS

The invention is further explained below with the aid of illustrations of exemplary embodiments. These show:

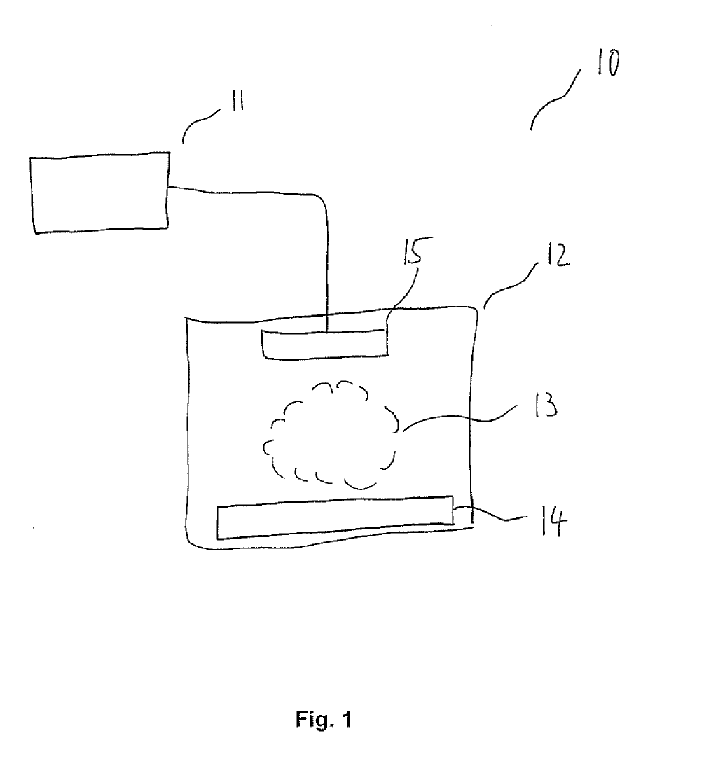

FIG. 1 a plasma chamber with sputter cathode with direct supply;

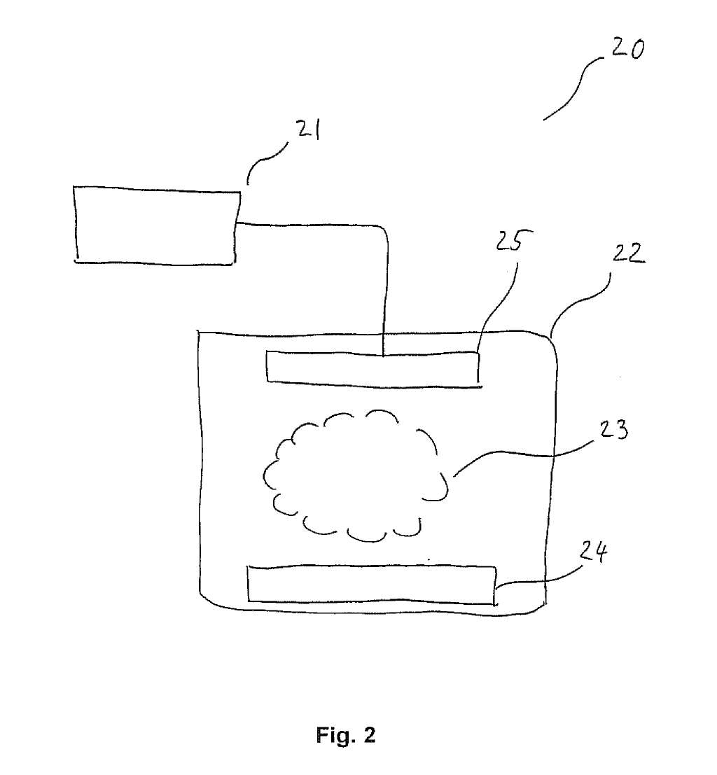

FIG. 2 a plasma chamber executed as an inductive coupled plasma (ICP) etching plant; and

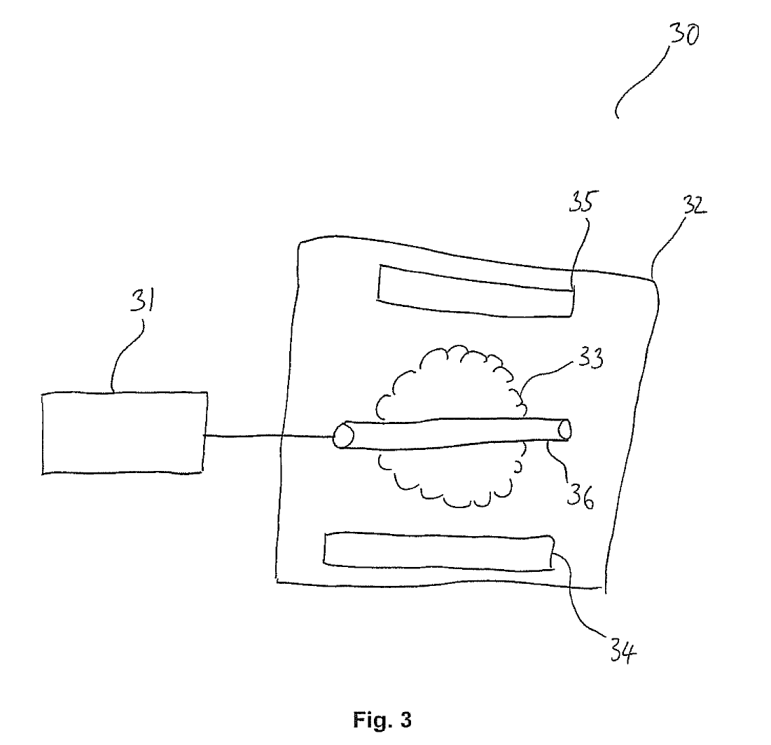

FIG. 3 a plasma chamber for sputtering via an inductive coupling.

### DETAILED DESCRIPTION OF THE ILLUSTRATIONS

FIG. 1 shows a plasma chamber 10 with a sputter cathode (target) 15 with a direct supply. The plasma chamber 10 comprises a vacuum chamber 12, in which the substrate 14 is disposed on a first side and the target 15 on a second side (opposite). In the vacuum chamber 12, a process gas environment suitable for sputtering and a plasma 13 is produced, which releases material from the target 15 through shock reactions, which can then be deposited on the substrate 14. The target 15 is directly connected to a high-frequency power supply 11, so that the high-frequency, modulated AC voltage generated by the high-frequency power supply 11 is directly applied to the target 15 and the target 15, as described, acts as a sputter cathode. According to the invention, a carrier frequency is chosen, which lies at the upper end of the self-bias voltage range or higher. Through the frequency conversion in the electrically non-linear plasma 13, there emerge in these low-frequency mixing products, through which a suitable self-bias voltage is generated and through which the high-frequency, modulated AC voltage can be adjusted essentially independently of the plasma density. In this way, the ion current (depending on the plasma density) can be adjusted independently of the ion energy (depending on the self-bias voltage). In addition, magnetic fields may be used—in the known manner—for plasma confinement.

The invention has the further advantage that a substrate bias is formed, which is useful for a plurality of coating processes. According to the state of the art, the substrate bias is achieved by a second power supply, which likewise supplies electrical energy to the substrate 14. However, this requires a second power supply with a compensating network, vacuum tube and substrate electrode. The latter may be very expensive to execute or may not even be achievable, e.g. with moved substrates 14. According to the invention, the substrate bias may only be generated by the high-frequency modulated AC voltage. This requires the substrate 14 to be only floating, in other words, to be electrically insulated. Where there are adequately insulating substrate materials, the self-insulation of the substrate 14 may also be sufficient. The surface of the substrate 14 is now charged, because the charge carrier cannot discharge. The frequency conversion of the high-frequency, modulated AC voltage leads to the creation of a self-bias voltage on the substrate 14 too.

The control of the self-bias voltages on target 15 and substrate 14 may also be combined according to the invention. A multi-tone signal is used for this, which contains different difference frequencies. These give rise to self-bias voltages on the target 15 and substrate 14, which can be adjusted by varying the modulation. As possibilities for varying the modulation, it is conceivable that the relative location of tones in the spectrum may be altered or the amount and phase of these adjusted. FIG. 2 shows a plasma chamber 2 executed as an inductive coupled plasma (ICP) etching plant. The operating modes of this exemplary embodiment and the example in FIG. 1 are essentially the same. In turn, a plasma 23 is generated in a vacuum chamber 22, in order to process a substrate 24 located in the vacuum chamber 22. However, high-frequency power generation 21 is connected to an ICP antenna 25 in this case, which acts inductively and thereby generates the plasma 23. In the state of the art, a high-frequency power supply is provided for the substrate 24 with ICP etching. This additional expenditure becomes superfluous due to the invention, because the substrate bias, as already described, can be generated through the demodulation of the ICP supply voltage in the plasma 23.

FIG. 3 shows a plasma chamber 30 for sputtering via an inductive coupling. Again, the mode of operation of the exemplary embodiment shown is very similar to that of the preceding exemplary embodiments. A high-frequency power generation 31 supplies an inductive antenna 36 with a high-frequency, modulated AC voltage and thereby produces a plasma 33 in a vacuum chamber 32. A target 35 is disposed floating in the vacuum chamber 32. A substrate 34 may likewise be disposed floating in the vacuum chamber 32, although it is conceivable that the substrate 34 will be set at a desired potential via a separate power supply. The self-bias voltage at the target 35 is in turn generated through frequency conversion of the high-frequency, modulated AC voltage produced by the high-frequency, voltage generation 31 in the plasma 33. Through further difference frequencies, a self-bias may also be achieved on the substrate 34. In this case, the substrate 34 must be disposed floating.

The examples described may also be executed similarly with carrier frequencies in the microwave range, wherein waveguide antennas, for example, can then be used to radiate electrical energy. Likewise, it is also conceivable that arrays of such antennas are used.

1. A plasma chamber (10, 20, 30) with a first receiving device for a substrate (14, 24, 34) fastened to a first side of a vacuum chamber (12, 22, 32) and with a plasma generation unit for generating plasma in the plasma chamber (10, 20, 30), wherein the plasma generation unit is connected or can be connected to a high-frequency voltage supply (11, 21, 31), characterised in that the high-frequency voltage supply (11, 21, 31) is designed to generate a modulated, high-frequency AC voltage and to deliver it to the plasma generation unit and that the plasma generation unit is designed to generate the plasma using the modulated, high-frequency AC voltage.

2. The plasma chamber (10, 20, 30) in claim 1, with a user interface for the input of a rated voltage value, wherein the high-frequency voltage supply (11, 21, 31) is designed to generate the modulated, high-frequency AC voltage at an amplitude indicated by the rated voltage value of a modulated signal.

3. The plasma chamber (10, 20, 30) in claim 1, with a measuring device, which is designed to determine a self-bias potential of the plasma in the plasma chamber and to deliver it as a measured value.

4. The plasma chamber (10, 20, 30) in claim 2, with a control unit which is connected to the user interface, the high-frequency voltage supply (11, 21, 31) and the measuring device and is designed to compare the measured value of the measuring device and the rated voltage value and to regulate the high-frequency voltage supply (11, 21, 31) in accordance with a result of the comparison, if the measured value on the measuring device deviates from the voltage value entered through the user interface.

5. The plasma chamber (10, 20, 30) in claim 1, in which the modulated, high-frequency AC voltage exhibits a mid-band frequency and a bandwidth,
wherein the mid-band frequency is preferably between 50 kHz and 10 GHz,
wherein the bandwidth is preferably smaller than the mid-band frequency
and wherein the bandwidth is preferably smaller than half the mid-band frequency.

6. The plasma chamber (10, 20, 30) in claim 1, in which the modulated, high-frequency AC voltage exhibits at least a first tone of a first frequency and a second tone of a second frequency, which differs from the first frequency by a difference frequency, the difference frequency being at least 25 kHz and preferably a maximum of 100 MHz.

7. The plasma chamber (10, 20, 30) in claim 1, in which the modulated, high-frequency AC voltage is a multi-tone signal.

8. The plasma chamber (10, 20, 30) in claim 1, in which the modulated, high-frequency AC voltage is an amplitude-modulated or digital-modulated signal.

9. The plasma chamber (10, 20, 30) in claim 1, in which the modulated, high-frequency AC voltage is a phase- or frequency-modulated signal.

10. The plasma chamber (10, 20, 30) in claim 1, in which a second receiving device for a target (15, 25, 35) is disposed on a second side of the vacuum chamber (12, 22, 32).
